(19) United States
(12) Patent Application Publication
(10) Pub. No.: US 2023/0097966 A1
(43) Pub. Date: Mar. 30, 2023

(54) PHOTOACTIVE COMPOSITION

(71) Applicant: Sumitomo Chemical Co., Ltd., Tokyo (JP)

(72) Inventors: Francisco Javier Rodriguez-Martinez, Godmanchester (GB); Nir Yaacobi-Gross, Godmanchester (GB)

(73) Assignee: Sumitomo Chemical Co., Ltd., Tokyo (JP)

(21) Appl. No.: 17/909,259

(22) PCT Filed: Mar. 4, 2021
(86) PCT No.: PCT/GB2021/050543

§ 371 Date: Sep. 2, 2022

(30) Foreign Application Priority Data
Mar. 6, 2020 (GB) 2003334.6

(51) Int. Cl. H01L 51/00

(52) U.S. Cl. CPC H01L 51/0036; H01L 51/0047; H01L 51/4253

(57) ABSTRACT

A composition comprising a first organic electron donor material having an absorption maximum greater than 900 nm; a second organic electron donor material having an absorption maximum at a shorter wavelength than the first organic electron donor material; and an organic electron acceptor material. The composition may be used in an organic photodetector.

### BACKGROUND

Embodiments of the present disclosure relate to organic photoactive compositions and uses thereof including, but not by way of limitation, to organic photodetectors containing said organic photoactive compositions.

US 2012/216866 discloses an organic photovoltaic cell having an organic layer containing a first electron donor compound, a second electron donor compound and an electron acceptor compound in which the difference between the highest occupied molecular orbital (HOMO) energy level of the first electron donor compound and the HOMO of the second electron donor compound is 0.20 eV or less.

### SUMMARY

In some embodiments, the present disclosure provides a composition comprising a first organic electron donor material having an absorption maximum greater than 900 nm; a second organic electron donor material having an absorption maximum at a shorter wavelength than the first organic electron donor material; and an organic electron acceptor material.

Optionally, the second organic electron donor material has an absorption maximum in the range of 700-900 nm.

Optionally, the first organic electron donor material:second organic electron donor material weight ratio is in the range of 70:30-30:70.

Optionally, at least one of the first organic electron donor and the second organic electron donor is a polymer.

Optionally, at least one of the first organic electron donor material and the second organic electron donor material is an electron donor polymer.

Optionally, at least one of the first organic electron donor material and the second organic electron donor material is an electron donor polymer comprising an electron donating repeat unit and an electron accepting unit.

Optionally, the electron donor polymer comprises an electron-donating repeat unit selected from formulae (I)-(XV):

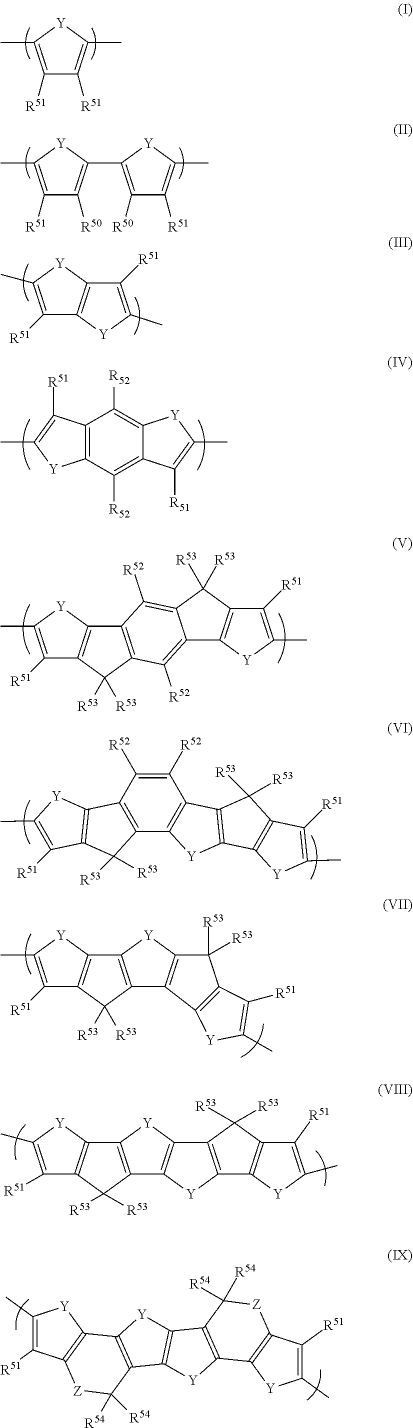

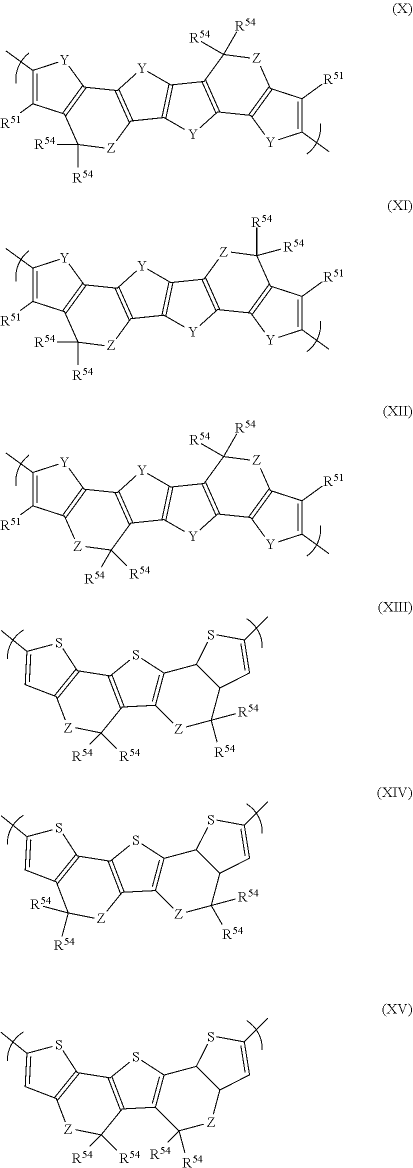

wherein Y in each occurrence is independently O or S, preferably S; Z in each occurrence is O, S, NR⁵⁵, or C(R⁵⁴)₂; R⁵⁰, R⁵¹, R⁵² and R⁵⁴ independently in each occurrence is H or a substituent wherein R⁵⁰ groups may be linked to form a ring; and R⁵³ and R⁵⁵ independently in each occurrence is H or a substituent.

Optionally, the electron donor polymer comprises an electron-accepting repeat unit selected from formulae (XVI)-(XXV):

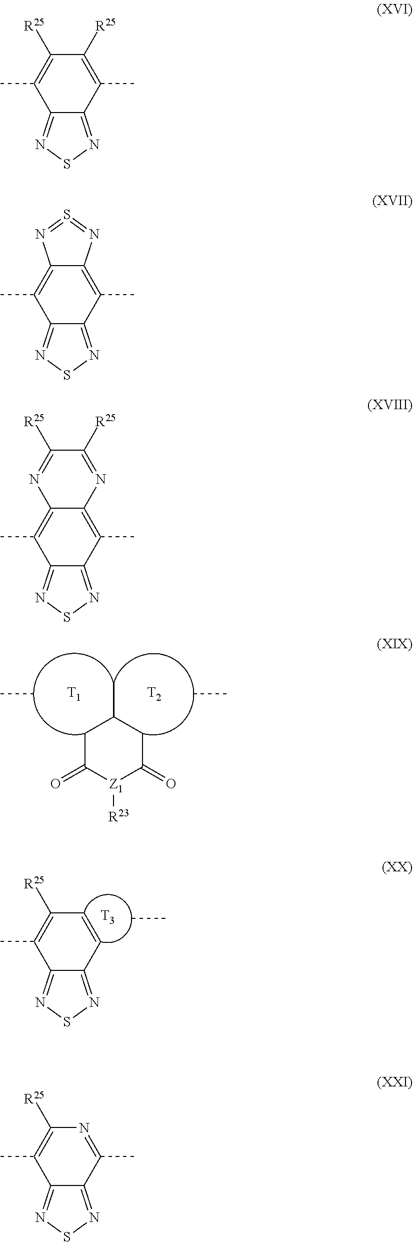

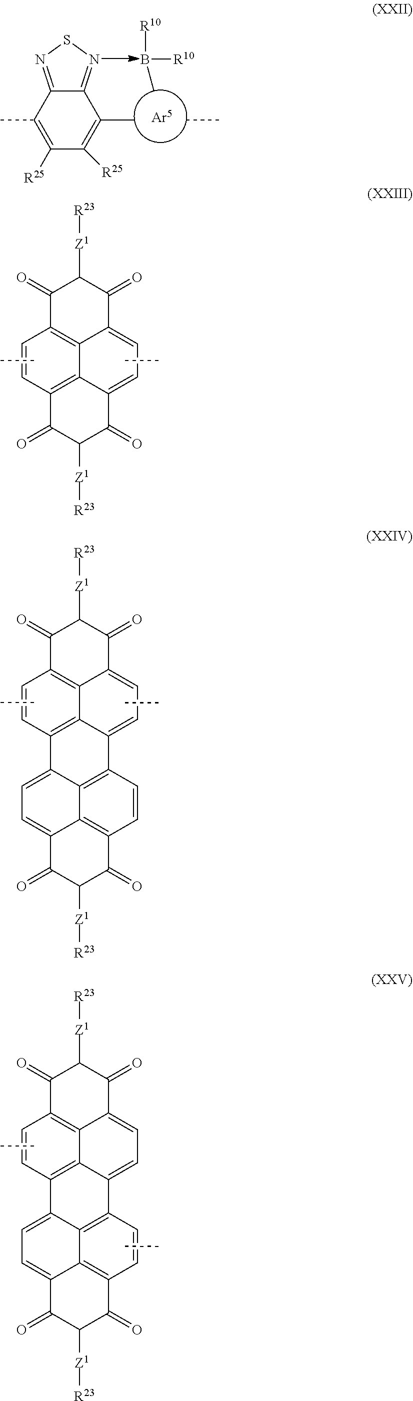

wherein R²³ in each occurrence is H or a substituent; R²⁵ in each occurrence is H or a substituent; Z¹ is N or P; T¹, T² and T³ each independently represent an aryl or a heteroaryl ring which may be fused to one or more further rings; R¹⁰ in each occurrence is a substituent; and Ar⁵ is an arylene or heteroarylene group which is unsubstituted or substituted with one or more substituents.

Optionally, the organic electron acceptor is a fullerene compound.

Optionally, the organic electron acceptor is a non-fullerene compound.

In some embodiments, the present disclosure provides a formulation comprising one or more solvents and a composition as described herein dissolved or dispersed in the one or more solvents.

In some embodiments, the present disclosure provides an organic photoresponsive device comprising an anode, a cathode and an organic photosensitive layer disposed between the anode and the cathode, wherein the organic photosensitive layer comprises a composition as described herein.

Optionally, the organic photoresponsive device is an organic photodetector.

In some embodiments, the present disclosure provides a method of forming an organic photoresponsive device as described herein comprising formation of the organic photosensitive layer over one of the anode and cathode and formation of the other of the anode and cathode over the organic photosensitive layer.

In some embodiments, the present disclosure provides a photosensor comprising a light source and an organic photoresponsive device as described herein configured to detect light emitted from the light source.

Optionally, the light source emits light having a peak wavelength of greater than 900 nm.

In some embodiments, the present disclosure provides a method of determining the presence and/or concentration of a target material in a sample, the method comprising illuminating the sample and measuring a response of an organic photoresponsive device as described herein.

### DESCRIPTION OF DRAWINGS

The disclosed technology and accompanying figures describe some implementations of the disclosed technology.

FIG. 1 illustrates an organic photoresponsive device according to some embodiments;

FIG. 2A is a graph of external quantum efficiency (EQE) for comparative organic photodetectors containing a single donor polymer;

FIG. 2B is a graph of current density versus voltage in dark conditions for the comparative organic photodetectors of FIG. 2A;

FIG. 3A is a graph of external quantum efficiency (EQE) for organic photodetectors according to embodiments of the present disclosure containing two donor polymers in different ratios and a fullerene electron acceptor;

FIG. 3B is a graph of current density versus voltage in dark conditions for the organic photodetectors of FIG. 3A;

FIG. 4A is a graph of external quantum efficiency (EQE) for organic photodetectors according to embodiments of the present disclosure containing two donor polymers in different ratios and a fullerene acceptor, and a comparative organic photodetector containing only one donor polymer;

FIG. 4B is a graph of current density versus voltage in dark conditions for the organic photodetectors of FIG. 4A;

FIG. 5A is a graph of external quantum efficiency (EQE) for organic photodetectors according to embodiments of the present disclosure containing two donor polymers in different ratios and a non-fullerene electron acceptor, and a comparative organic photodetector containing only one donor polymer;

FIG. 5B is a graph of current density versus voltage in dark conditions for the organic photodetectors of FIG. 5A; and

FIG. 6 is absorption spectra for two donor polymers of a composition according to some embodiments of the present disclosure.

The drawings are not drawn to scale and have various viewpoints and perspectives. The drawings are some implementations and examples. Additionally, some components and/or operations may be separated into different blocks or combined into a single block for the purposes of discussion of some of the embodiments of the disclosed technology. Moreover, while the technology is amenable to various modifications and alternative forms, specific embodiments have been shown by way of example in the drawings and are described in detail below. The intention, however, is not to limit the technology to the particular implementations described. On the contrary, the technology is intended to cover all modifications, equivalents, and alternatives falling within the scope of the technology as defined by the appended claims.

### DETAILED DESCRIPTION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” Additionally, the words “herein,” “above,” “below,” and words of similar import, when used in this application, refer to this application as a whole and not to any particular portions of this application. Where the context permits, words in the Detailed Description using the singular or plural number may also include the plural or singular number respectively. The word “or,” in reference to a list of two or more items, covers all of the following interpretations of the word: any of the items in the list, all of the items in the list, and any combination of the items in the list. References to a layer “over” another layer when used in this application means that the layers may be in direct contact or one or more intervening layers are may be present. References to a layer “on” another layer when used in this application means that the layers are in direct contact. References to a specific atom include any isotope of that atom unless specifically stated otherwise.

The teachings of the technology provided herein can be applied to other systems, not necessarily the system described below. The elements and acts of the various examples described below can be combined to provide further implementations of the technology. Some alternative implementations of the technology may include not only additional elements to those implementations noted below, but also may include fewer elements.

These and other changes can be made to the technology in light of the following detailed description. While the description describes certain examples of the technology, and describes the best mode contemplated, no matter how detailed the description appears, the technology can be practiced in many ways. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the Detailed Description section explicitly defines such terms.

Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms.

In the following description, for the purposes of explanation, numerous specific details are set forth in order to provide a thorough understanding of implementations of the disclosed technology. It will be apparent, however, to one skilled in the art that embodiments of the disclosed technology may be practiced without some of these specific details.

The present inventors have found that measures to increase the external quantum efficiency (EQE) of an organic photodetector (OPD), particularly EQE at long wavelengths such as the near infra-red region, may result in an increase in dark current, i.e. current flowing through the device in the absence of any input light. This may limit the sensitivity of the OPD. The present inventors have surprisingly found that use of two different electron donor materials having different absorption maxima in the bulk heterojunction layer of an OPD may result in lower dark current and maintenance of high EQE as compared to an OPD having only the electron donor material having the longer absorption maximum.

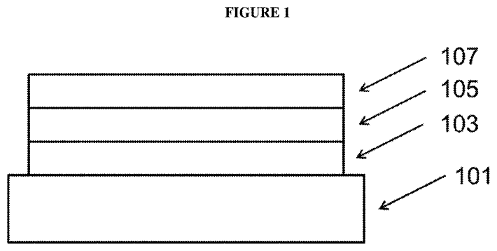

FIG. 1 illustrates an organic photoresponsive device according to some embodiments of the present disclosure. The organic photoresponsive device comprises a cathode 103, an anode 107 and a bulk heterojunction layer 105 disposed between the anode and the cathode. The organic photoresponsive device may be supported on a substrate 101, optionally a glass or plastic substrate.

Each of the anode and cathode may independently be a single conductive layer or may comprise a plurality of layers.

The organic photoresponsive device may comprise layers other than the anode, cathode and bulk heterojunction layer shown in FIG. 1. In some embodiments, a hole-transporting layer is disposed between the anode and the bulk heterojunction layer. In some embodiments, an electron-transporting layer is disposed between the cathode and the bulk heterojunction layer. In some embodiments, a work function modification layer is disposed between the bulk heterojunction layer and the anode, and/or between the bulk heterojunction layer and the cathode.

The area of the OPD may be less than about 3 cm², less than about 2 cm², less than about 1 cm², less than about 0.75 cm², less than about 0.5 cm² or less than about 0.25 cm². The substrate may be, without limitation, a glass or plastic substrate. The substrate can be an inorganic semiconductor. In some embodiments, the substrate may be silicon. For example, the substrate can be a wafer of silicon. The substrate is transparent if, in use, incident light is to be transmitted through the substrate and the electrode supported by the substrate.

The bulk heterojunction layer contains two different electron donor materials and an electron acceptor material. The bulk heterojunction layer may consist of these materials or may comprise one or more further materials, for example one or more further electron donor materials and/or one or more further electron acceptor materials.

Each electron donor (p-type) material has a HOMO deeper (further from vacuum level) than a LUMO of the electron acceptor (n-type) material. The electron-accepting material has a LUMO that is deeper than the LUMO of each of the electron donor materials. Optionally, the gap between the HOMO level of each of the p-type donor materials and the LUMO level of the n-type acceptor material is less than 1.4 eV. Unless stated otherwise, HOMO and LUMO levels of materials as described herein are as measured by square wave voltammetry (SWV).

Optionally, the first electron donor material has a LUMO that is at least 0.1 eV deeper, optionally at least 0.2 eV deeper, than the LUMO of the second electron donor material. In SWV, the current at a working electrode is measured while the potential between the working electrode and a reference electrode is swept linearly in time. The difference current between a forward and reverse pulse is plotted as a function of potential to yield a voltammogram. Measurement may be with a CHI 660D Potentiostat.

The apparatus to measure HOMO or LUMO energy levels by SWV may comprise a cell containing 0.1 M tertiary butyl ammonium hexafluorophosphate in acetonitrile; a 3 mm diameter glassy carbon working electrode; a platinum counter electrode and a leak free Ag/AgCl reference electrode.

Ferrocene is added directly to the existing cell at the end of the experiment for calculation purposes where the potentials are determined for the oxidation and reduction of ferrocene versus Ag/AgCl using cyclic voltammetry (CV).

The sample is dissolved in Toluene (3 mg/ml) and spun at 3000 rpm directly on to the glassy carbon working electrode.

LUMO=4.8-E ferrocene (peak to peak average)−E reduction of sample (peak maximum).

HOMO=4.8-E ferrocene (peak to peak average)+E oxidation of sample (peak maximum).

A typical SWV experiment runs at 15 Hz frequency; 25 mV amplitude and 0.004 V increment steps. Results are calculated from 3 freshly spun film samples for both the HOMO and LUMO data.

In some embodiments, the weight ratio of the donor materials to the acceptor material(s) is from about 1:0.5 to about 1:2. In some preferred embodiments, the weight ratio of the donor materials to the acceptor material(s) is about 1:1.1 to about 1:2. In some preferred embodiments, the weight of the donor materials is greater than the weight of the acceptor material(s).

In some embodiments, the weight ratio of the first donor material to the second donor material is in the range of 80:20-20:80, preferably 70:30-30:70. In some preferred embodiments, the weight of the first donor material is at least the same as the weight of the second donor material, e.g. in the range of 50:50-80:20.

A first electron donor material of the bulk heterojunction layer has an absorption maximum greater than 900 nm, optionally in the range of 910-1600 nm.

A second electron donor material of the bulk heterojunction layer has an absorption maximum at a shorter wavelength than the first electron donor material, optionally at least 50 nm or at least 100 nm shorter than the first electron donor material. Optionally, the second electron donating has an absorption maximum in the range of 500-900 nm, optionally 700-900 nm, optionally 750-850 nm.

An absorption maximum as described herein may be as measured in solution, optionally toluene solution, using a Cary 5000 UV-vis-IR spectrometer. Measurements may be taken from 175 nm to 3300 nm using a PbSmart NIR detector for extended photometric range with variable slit widths (down to 0.01 nm) for optimum control over data resolution.

Absorption intensity is plotted vs. incident wavelength to generate an absorption spectrum. A method for measuring film absorption, may comprise measuring a 15 mg/ml solution in a quartz cuvette and comparing to a cuvette containing the solvent only.

Preferably at least one, more preferably both, of the first and second electron donor materials are polymers.

Preferably, the polystyrene-equivalent number-average molecular weight (Mn) measured by gel permeation chromatography of a first or second electron donor polymer is in the range of about 5×10³ to 1×10⁸, and preferably 1×10⁴ to 5×10⁶. The polystyrene-equivalent weight-average molecular weight (Mw) of the polymers may be 1×10³ to 1×10⁸, and preferably 1×10⁴ to 1×10⁷.

Preferred first and second electron donor polymers contain alternating electron-accepting repeat units and electron-donating repeat units.

The electron-accepting repeat unit has a LUMO level that is deeper (i.e. further from vacuum) than the electron-donating repeat unit, preferably at least 1 eV deeper. The LUMO levels of electron-donating repeat units and electron-accepting repeat units may be as determined by modelling the LUMO level of each repeat unit, in which bonds to adjacent repeat units are replaced with bonds to a hydrogen atom. Modelling may be performed using Gaussian09 software available from Gaussian using Gaussian09 with B3LYP (functional) and LACVP* (Basis set).

Electron-donating repeat units are preferably in each occurrence a monocyclic or polycyclic heteroaromatic group which contains at least one furan or thiophene and which may be unsubstituted or substituted with one or more substituents. Preferred electron-donating repeat units are monocyclic thiophene or furan or a polycyclic donor repeat unit wherein each ring of the polycyclic donor includes thiophene or furan rings and, optionally, one or more of benzene, cyclopentane, or a six-membered ring containing 5 C atoms and one of N, S and O atoms.

Optionally, an electron donating repeat unit of at least one of the first and second electron donor polymers is selected from formulae (I)-(XV):

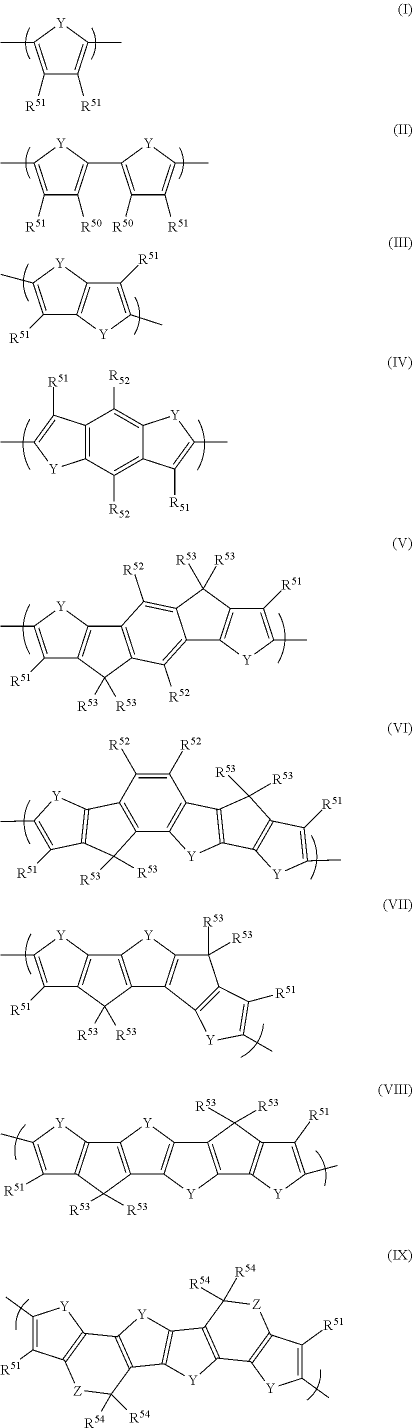

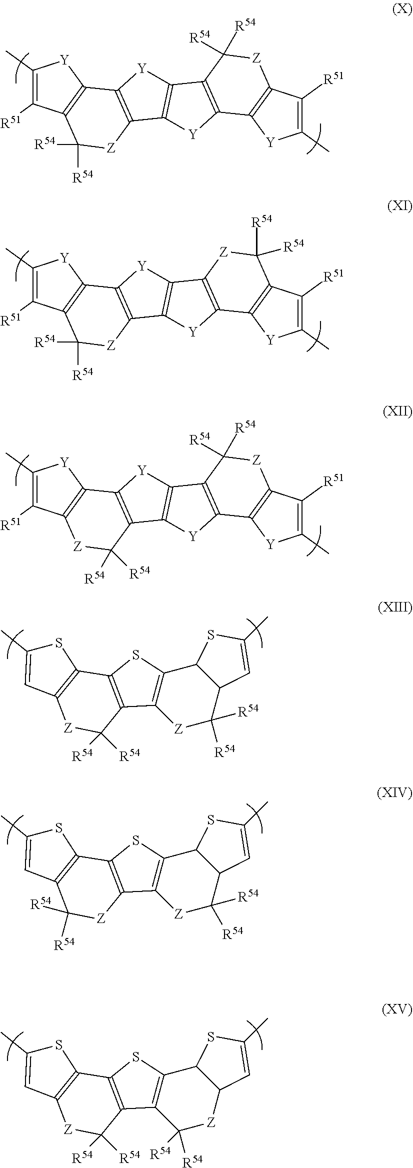

wherein Y in each occurrence is independently O or S, preferably S; Z in each occurrence is O, S, NR⁵⁵, or C(R⁵⁴)₂; R⁵⁰, R⁵¹, R⁵² and R⁵⁴ independently in each occurrence is H or a substituent wherein R⁵⁰ groups may be linked to form a ring; and R⁵³ and R⁵⁵ independently in each occurrence is H or a substituent.

Optionally, R⁵⁰, R⁵¹ and R⁵² independently in each occurrence are selected from H; F; C₁₋₂₀ alkyl wherein one or more non-adjacent, non-terminal C atoms may be replaced with O, S, COO or CO and one or more H atoms of the alkyl may be replaced with F; and an aromatic or heteroaromatic group Ar³ which is unsubstituted or substituted with one or more substituents.

In some embodiments, Ar³ maybe an aromatic group, e.g. phenyl.

The one or more substituents of Ar³, if present, may be selected from C₁₋₁₂ alkyl wherein one or more non-adjacent, non-terminal C atoms may be replaced with O, S, COO or CO and one or more H atoms of the alkyl may be replaced with F.

By “non-terminal” C atom of an alkyl group as used herein is meant a C atom of the alkyl other than the methyl C atom of a linear (n-alkyl) chain or the methyl C atoms of a branched alkyl chain.

Preferably, each R⁵⁴ is selected from the group consisting of:

H;

linear, branched or cyclic C₁₋₂₀ alkyl wherein one or more non-adjacent, non-terminal C atoms may be replaced by O, S, NR⁷, CO or COO wherein R⁷ is a C₁₋₁₂ hydrocarbyl and one or more H atoms of the C₁₋₂₀ alkyl may be replaced with F; and

a group of formula -(Ak)u-(Ar⁴)v wherein Ak is a C₁₋₁₂ alkylene chain in which one or more C atoms may be replaced with O, S, CO or COO; u is 0 or 1; Ar⁴ in each occurrence is independently an aromatic or heteroaromatic group which is unsubstituted or substituted with one or more substituents; and v is at least 1, optionally 1, 2 or 3.

Preferably, each R⁵¹ is H.

Optionally, R⁵³ independently in each occurrence is selected from C₁₋₂₀ alkyl wherein one or more non-adjacent, non-terminal C atoms may be replaced with O, S, COO or CO and one or more H atoms of the alkyl may be replaced with F; and phenyl which is unsubstituted or substituted with one or more substituents, optionally one or more C₁₋₁₂ alkyl groups wherein one or more non-adjacent, non-terminal C atoms may be replaced with O, S, COO or CO and one or more H atoms of the alkyl may be replaced with F.

Preferably, R⁵⁵ is H or a C₁₋₃₀ hydrocarbyl group.

Formulae (II)-(IV) are preferred.

Preferably, each R⁵⁰ is a substituent. In a preferred embodiment, the R⁵⁰ groups are linked to form a group of formula —(Z)q-C(R⁵⁴)₂— wherein Z is O, S, NR⁵⁵, or C(R⁵⁴)₂ and q is 0 or 1, e.g. a group of formula (IIa), (IIb) or (IIc):

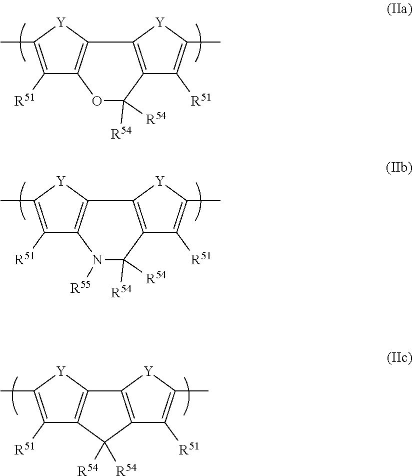

Preferably, q=1.

Electron-donating repeat units of formula (IIa) and (IIb) are particularly preferred.

The first and second donor polymers described herein may each independently contain only one donor repeat unit or two or more different donor repeat units, e.g. two or more different donor repeat units selected from formulae (I)-(XV).

In some embodiments, the first and/or second donor polymer contains one donor repeat unit selected from one of formulae (I)-(XV) and another donor repeat unit selected from another of formulae (I)-(XV).

In some embodiments, the first and/or second donor polymer contains one donor repeat unit selected from one of formulae (I)-(XV) and another donor repeat unit selected from the same one of formulae (I)-(XV), e.g. a donor repeat unit selected from one of formulae (IIa)-(IIc) and another donor repeat unit selected from another of formulae (IIa)-(IIc).

Optionally, the first electron donor material and the second electron donor material are polymers wherein the first and second polymer comprise the same electron-donating repeat unit or repeat units, optionally the same electron donating repeat unit or repeat units selected from formulae (I)-(XV).

Optionally, an electron-accepting repeat unit of at least one of the first and second electron donor polymers is selected from formulae (XVI)-(XXV):

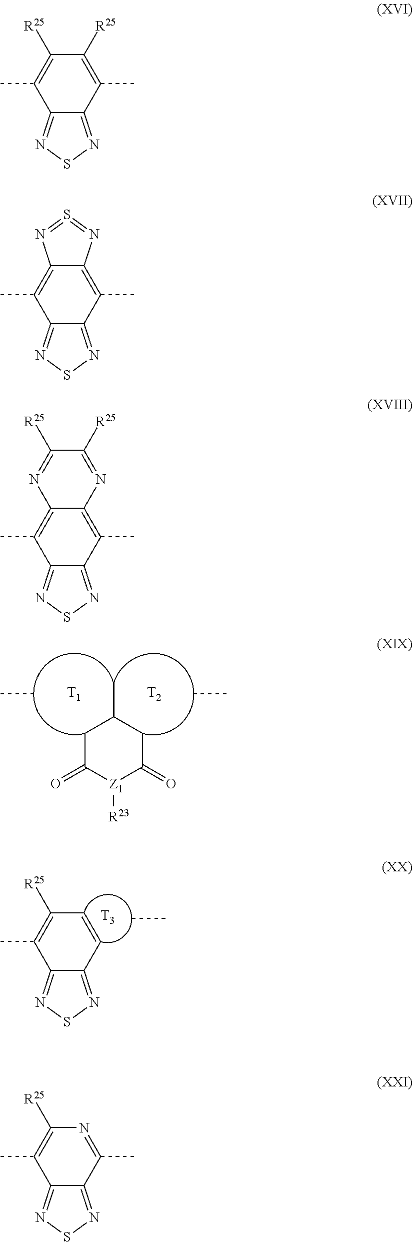

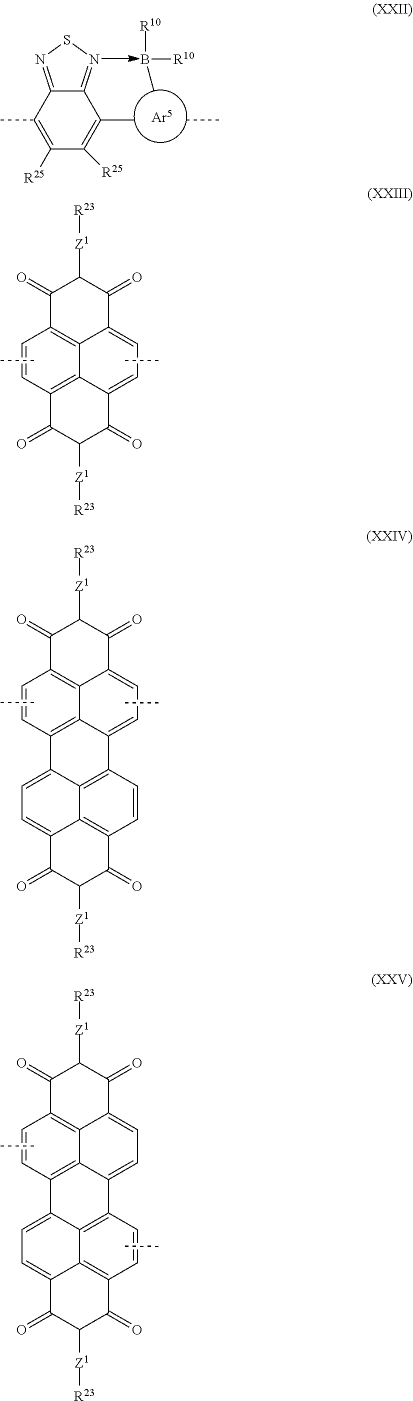

R²³ in each occurrence is H or a substituent, optionally H or C₁₋₁₂ alkyl wherein one or more non-adjacent, non-terminal C atoms may be replaced with O, S, COO or CO and one or more H atoms of the alkyl may be replaced with F.

R²⁵ in each occurrence is independently H; F; C₁₋₁₂ alkyl wherein one or more non-adjacent, non-terminal C atoms may be replaced with O, S, COO or CO and one or more H atoms of the alkyl may be replaced with F; or an aromatic group Ar², optionally phenyl, which is unsubstituted or substituted with one or more substituents selected from F and C₁₋₁₂ alkyl wherein one or more non-adjacent, non-terminal C atoms may be replaced with O, S, COO or CO.

Z¹ is N or P.

T¹, T² and T³ each independently represent an aryl or a heteroaryl ring, optionally benzene, which may be fused to one or more further rings. Substituents of T¹, T² and T³, where present, are optionally selected from non-H groups of R²⁵. Optionally, T³ is benzothiadiazole and the repeat unit of formula (XX) has formula (XXa):

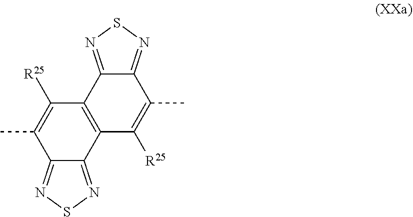

R¹⁰ in each occurrence is a substituent, preferably a C₁₋₂₀ hydrocarbyl group.

Ar⁵ is an arylene or heteroarylene group, optionally thiophene, fluorene or phenylene, which may be unsubstituted or substituted with one or more substituents, optionally one or more non-H groups selected from R²⁵.

Optionally, the composition comprises first and second electron donor polymers having different electron-accepting repeat units. Optionally, the first and second electron-donating polymers have different electron-accepting repeat units selected from formulae (XVI)-((XXV).

Exemplary electron donor polymers are disclosed in, for example, WO2013/051676, the contents of which are incorporated herein by reference.

Electron Acceptor Material

The electron acceptor material is preferably a non-polymeric compound. Preferably, the non-polymeric compound has a molecular weight of less than 5,000 Daltons, optionally less than 3,000 Daltons.

The electron acceptor material may be a fullerene or a non-fullerene

Non-fullerene acceptors are described in, for example, Cheng et al, “Next-generation organic photovoltaics based on non-fullerene acceptors”, Nature Photonics volume 12, pages 131-142 (2018), the contents of which are incorporated herein by reference, and which include, without limitation, PDI, ITIC, ITIC, IEICO and derivatives thereof, e.g. fluorinated derivatives thereof such as ITIC-4F and IEICO-4F.

Exemplary fullerene electron acceptor materials are C₆₀, C₇₀, C₇₆, C₇₈ and C₈₄ fullerenes or a derivative thereof including, without limitation, PCBM-type fullerene derivatives (including phenyl-C61-butyric acid methyl ester (C₆₀PCBM), TCBM-type fullerene derivatives (e.g. tolyl-C61-butyric acid methyl ester (C₆₀TCBM)), and ThCBM-type fullerene derivatives (e.g. thienyl-C61-butyric acid methyl ester (C₆₀ThCBM).

Electrodes

At least one of the anode and cathode is transparent so that light incident on the device may reach the bulk heterojunction layer. In some embodiments, both of the anode and cathode are transparent.

Each transparent electrode preferably has a transmittance of at least 70%, optionally at least 80%, to wavelengths in the range of 750-1000 nm. The transmittance may be selected according to an emission wavelength of a light source for use with the organic photodetector.

FIG. 1 illustrates an arrangement in which the cathode is disposed between the substrate and the anode. In other embodiments, the anode may be disposed between the cathode and the substrate.

Bulk Heterojunction Layer Formation

The bulk heterojunction layer may be formed by any process including, without limitation, thermal evaporation and solution deposition methods.

Preferably, the bulk heterojunction layer is formed by depositing a formulation comprising the electron donor materials, the electron acceptor material(s) and any other components of the bulk heterojunction layer dissolved or dispersed in a solvent or a mixture of two or more solvents. The formulation may be deposited by any coating or printing method including, without limitation, spin-coating, dip-coating, roll-coating, spray coating, doctor blade coating, wire bar coating, slit coating, ink jet printing, screen printing, gravure printing and flexographic printing.

The one or more solvents of the formulation may optionally comprise or consist of benzene substituted with one or more substituents selected from chlorine, C_{1_10} alkyl and C₁₋₁₀ alkoxy wherein two or more substituents may be linked to form a ring which may be unsubstituted or substituted with one or more C₁₋₆ alkyl groups, optionally toluene, xylenes, trimethylbenzenes, tetramethylbenzenes, anisole, indane and its alkyl-substituted derivatives, and tetralin and its alkyl-substituted derivatives.

The formulation may comprise a mixture of two or more solvents, preferably a mixture comprising at least one benzene substituted with one or more substituents as described above and one or more further solvents. The one or more further solvents may be selected from esters, optionally alkyl or aryl esters of alkyl or aryl carboxylic acids, optionally a C_{1_10} alkyl benzoate, benzyl benzoate or dimethoxybenzene. In preferred embodiments, a mixture of trimethylbenzene and benzyl benzoate is used as the solvent. In other preferred embodiments, a mixture of trimethylbenzene and dimethoxybenzene is used as the solvent.

The formulation may comprise further components in addition to the electron acceptor, the electron donor and the one or more solvents. As examples of such components, adhesive agents, defoaming agents, deaerators, viscosity enhancers, diluents, auxiliaries, flow improvers colourants, dyes or pigments, sensitizers, stabilizers, nanoparticles, surface-active compounds, lubricating agents, wetting agents, dispersing agents and inhibitors may be mentioned.

Applications

A circuit may comprise the OPD connected to a voltage source for applying a reverse bias to the device and/or a device configured to measure photocurrent. The voltage applied to the photodetector may be variable. In some embodiments, the photodetector may be continuously biased when in use.

In some embodiments, a photodetector system comprises a plurality of photodetectors as described herein, such as an image sensor of a camera.

In some embodiments, a sensor may comprise an OPD as described herein and a light source wherein the OPD is configured to receive light emitted from the light source. In some embodiments, the light source has a peak wavelength greater than 900 nm, optionally in the range of 910-1000 nm. In some embodiments, the light source has a peak wavelength greater than 1000 nm, optionally in the range of 1300-1400 nm.

In some embodiments, the light from the light source may or may not be changed before reaching the OPD. For example, the light may be reflected, filtered, down-converted or up-converted before it reaches the OPD.

The organic photoresponsive device as described herein may be an organic photovoltaic device or an organic photodetector. An organic photodetector as described herein may be used in a wide range of applications including, without limitation, detecting the presence and/or brightness of ambient light and in a sensor comprising the organic photodetector and a light source. The photodetector may be configured such that light emitted from the light source is incident on the photodetector and changes in wavelength and/or brightness of the light may be detected, e.g. due to absorption by, reflection by and/or emission of light from an object, e.g. a target material in a sample disposed in a light path between the light source and the organic photodetector. The sample may be a non-biological sample, e.g. a water sample, or a biological sample taken from a human or animal subject. The sensor may be, without limitation, a gas sensor, a biosensor, an X-ray imaging device, an image sensor such as a camera image sensor, a motion sensor (for example for use in security applications) a proximity sensor or a fingerprint sensor. A 1D or 2D photosensor array may comprise a plurality of photodetectors as described herein in an image sensor. The photodetector may be configured to detect light emitted from a target analyte which emits light upon irradiation by the light source or which is bound to a luminescent tag which emits light upon irradiation by the light source. The photodetector may be configured to detect a wavelength of light emitted by the target analyte or a luminescent tag bound thereto.

### EXAMPLES

Comparative Device A

A device having the following structure was prepared:

Cathode/Donor: Acceptor layer/Anode

A glass substrate coated with a layer of indium-tin oxide (ITO) was treated with polyethyleneimine (PEIE) to modify the work function of the ITO.

A mixture of Donor Polymer 1, having an absorption maximum of 933 nm, and fullerene electron acceptor C70IPH in a donor:acceptor mas ratio of 1:1.5 was deposited over the modified ITO layer by bar coating from a 15 mg/ml solution in 1,2,4 Trimethylbenzene; 1,3-Dimethoxybenzene 9:1 v/v solvent mixture. The film was dried at 80° C. to form a ca. 500 nm thick bulk heterojunction layer

An anode (Clevios HIL-E100) available from Heraeus was formed over the bulk heterojunction layer by spin-coating.

Comparative Device B

A device was prepared as described for Comparative Device 1 except that Donor Polymer 2, having an absorption maximum of about 800 nm, was used in place of Donor Polymer 1 and 60PCBM was used in place of C70IPH.

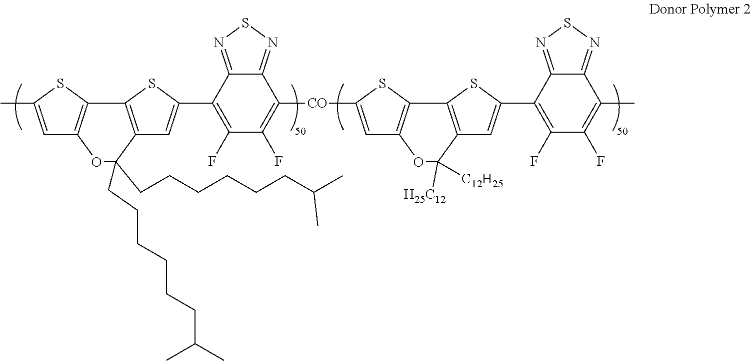

External quantum efficiencies (EQE) and dark currents of Comparative Device A and Comparative Device B were measured under a bias of 3 V.

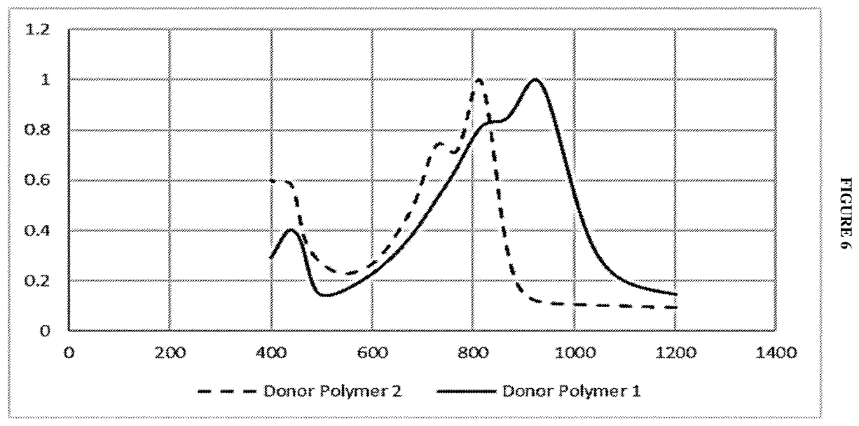

The absorption spectra of Donor Polymers 1 and 2 are shown in FIG. 6.

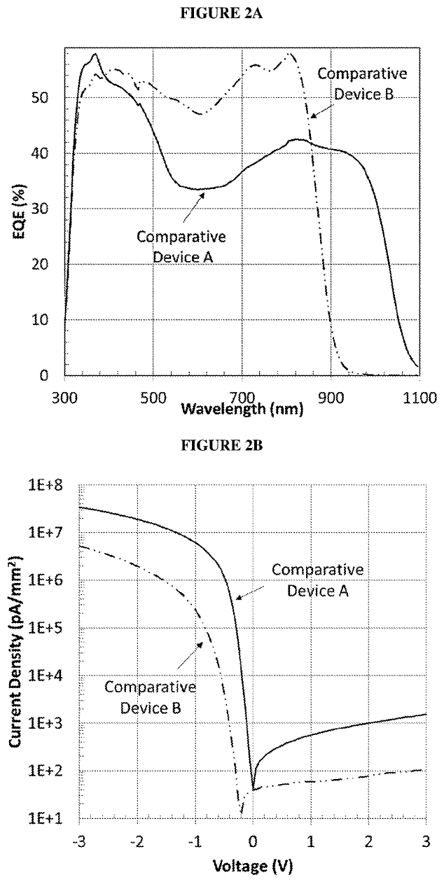

With reference to FIGS. 2A and 2B, Comparative Device A shows much higher external quantum efficiency than Comparative Device B at wavelengths above about 900 nm but also much higher dark current.

### Device Examples 1A-1C

A device having the following structure was prepared:

Cathode/Donor: Acceptor layer/Anode

A glass substrate coated with a layer of indium-tin oxide (ITO) was treated with polyethyleneimine (PEIE) to modify the work function of the ITO.

A mixture of Donor Polymer 1 and Donor Polymer 2 and fullerene electron acceptor 60PCBM in which the weight ratio of the combined donor polymers:acceptor was 1:1.5 was deposited over the modified ITO layer by bar coating from a 15 mg/ml solution in 1,2,4 Trimethylbenzene; 1,3-Dimethoxybenzene 9:1 v/v solvent mixture. The film was dried at 80° C. to form a ca. 500 nm thick bulk heterojunction layer.

An anode (Clevios HIL-E100) available from Heraeus was formed over the bulk heterojunction layer by spin-coating.

The weight ratios of Donor Polymer 1:Donor Polymer 2 are given in Table 1.

TABLE 1

| | Donor Polymer 1: |
|---|---|
| Device | Donor Polymer 2 |
| Example | weight ratio |
| 1A | 1:1 |
| 1B | 4:1 |
| 1C | 1:4 |

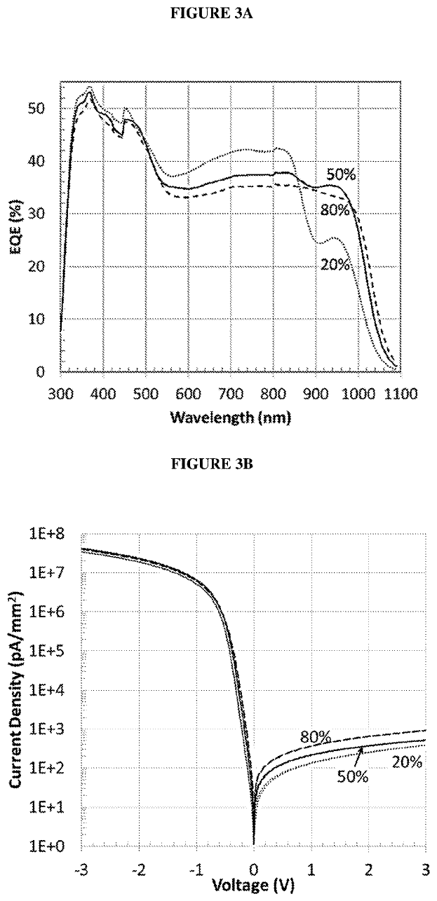

With reference to FIG. 3A, all exemplary devices show significant EQE at wavelengths above 900 nm. Devices in which Donor Polymer 1 forms at least 50 weight % of the donor polymers have the highest EQE at above 900 nm (percentages shown in FIGS. 3A, 3B, 4A, 4B, 5A and 5B are the Donor Polymer 1 weight percent of Donor Polymer 1 and Donor Polymer 2).

With reference to FIG. 3B, dark current increases with increasing proportion of Donor Polymer 1.

### Device Examples 2A and 2B

Device Examples 2A and 2B were formed as described for Device Examples 1A-1C except that the weight ratio of the combined donor polymers:60PCBM was 1:1.75.

The weight ratios of Donor Polymer 1:Donor Polymer 2 are given in Table 2.

TABLE 2

| | Donor Polymer 1: |
|---|---|
| Device | Donor Polymer 2 |
| Example | weight ratio |
| 2A | 1:1 |
| 2B | 4:1 |

Comparative Device 2

Comparative Device 2 was formed as described for Device Examples 2A and 2B except that Donor Polymer 1 was the sole donor material.

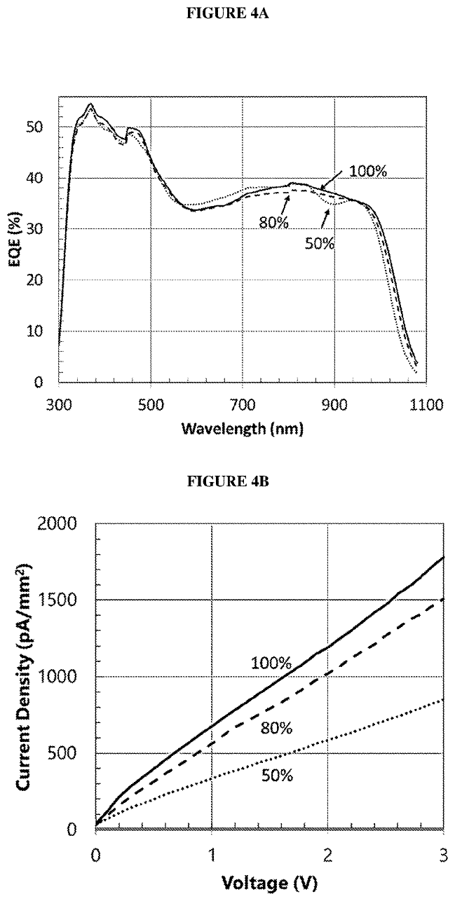

With reference to FIG. 4A, Device Examples 2A and 2B (50 wt % and 80 wt % Donor Polymer 1, respectively) show similar EQE to Comparative Device 2 (100 wt % Donor Polymer 1).

With reference to FIG. 4B, Comparative Device 2 suffers from significantly higher dark current than either Device Example 2A or 2B.

### Device Examples 3A and 3B

Device Examples 3A and 3B were formed as described for Device Examples 1A-1C except that non-fullerene acceptor ITIC-2F was used in place of 60PCBM.

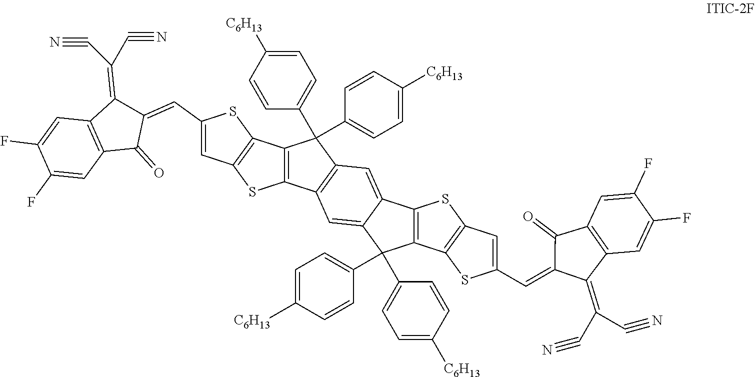

The weight ratios of Donor Polymer 1:Donor Polymer 2 are given in Table 3.

TABLE 3

| | Donor Polymer 1: |
|---|---|
| Device | Donor Polymer 2 |
| Example | weight ratio |
| 3A | 1:1 |
| 3B | 3:1 |

Comparative Device 3

Comparative Device 3 was formed as described for Device Examples 3A and 3B except that Donor Polymer 1 was the sole donor material.

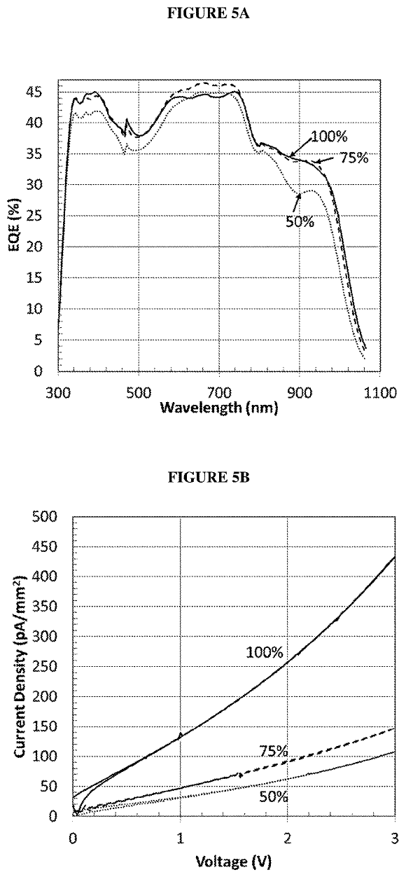

With reference to FIG. 5A, Device Examples 3A and 3B (50 wt % and 75 wt % Donor Polymer 1, respectively) show similar EQE to Comparative Device 3 (100 wt % Donor Polymer 1).

With reference to FIG. 5B, Comparative Device 3 suffers from significantly higher dark current than either Device Example 3A or 3B.

1. A composition comprising a first organic electron donor material having an absorption maximum greater than 900 nm; a second organic electron donor material having an absorption maximum at a shorter wavelength than the first organic electron donor material; and an organic electron acceptor material.

2. The composition according to claim 1 wherein the second organic electron donor material has an absorption maximum in the range of 700-900 nm.

3. The composition according to claim 1 wherein the first organic electron donor material:second organic electron donor material weight ratio is in the range of 70:30-30:70,

4. The composition according to claim 1 wherein at least one of the first organic electron donor and the second organic electron donor is a polymer.

5. The composition according to claim 4, wherein at least one of the first organic electron donor material and the second organic electron donor material is an electron donor polymer.

6. The composition according to claim 5 wherein at least one of the first organic electron donor material and the second organic electron donor material is an electron donor polymer comprising an electron donating repeat unit and an electron accepting unit.

7. The composition according to claim 6 wherein the electron donor polymer comprises an electron-donating repeat unit selected from formulae (I)-(XV): 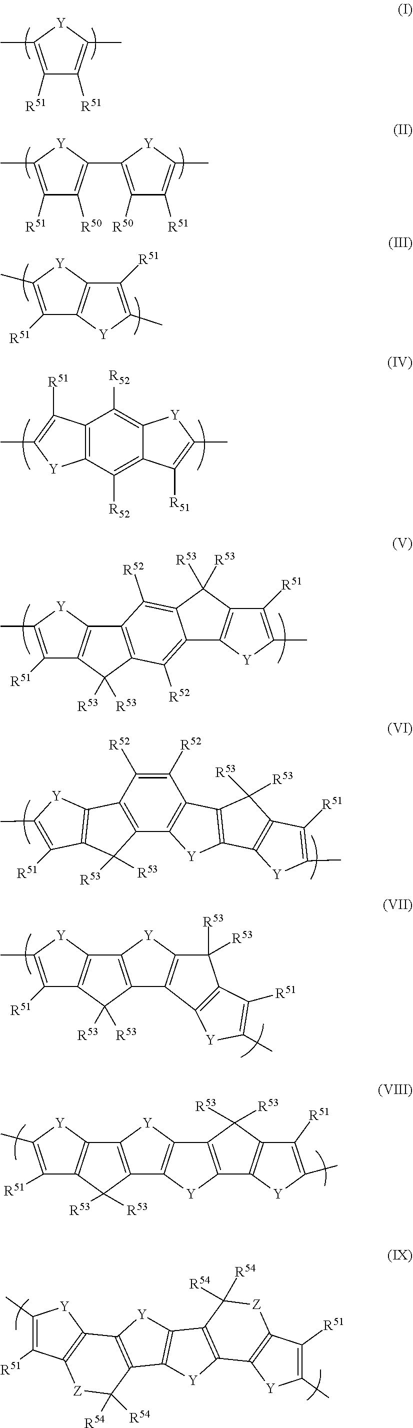 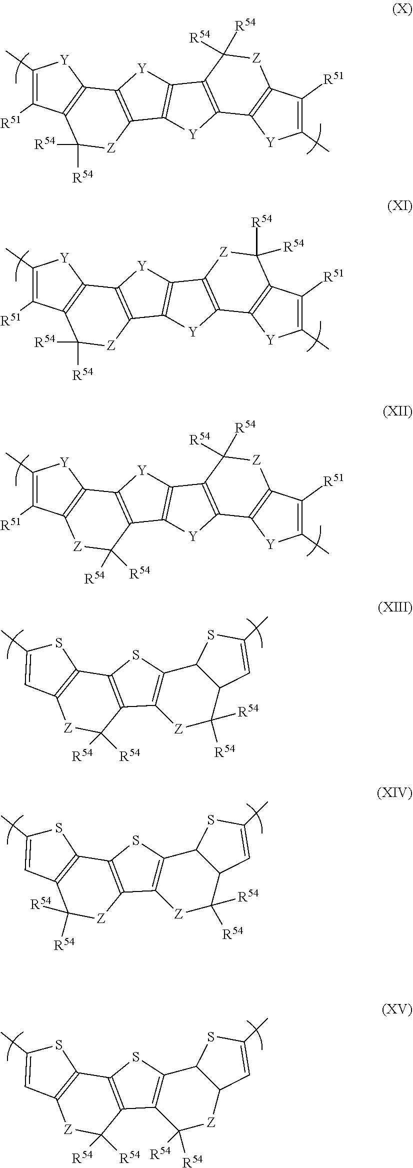
wherein Y in each occurrence is independently O or S, preferably S; Z in each occurrence is O, S, NR⁵⁵, or C(R⁵⁴)₂; R⁵⁰, R⁵¹, R⁵² and R⁵⁴ independently in each occurrence is H or a substituent wherein R⁵⁰ groups may be linked to form a ring; and R⁵³ and R⁵⁵ independently in each occurrence is H or a substituent.

8. The composition according to claim 6, wherein the electron donor polymer comprises an electron-accepting repeat unit selected from formulae (XVI)-(XXV): 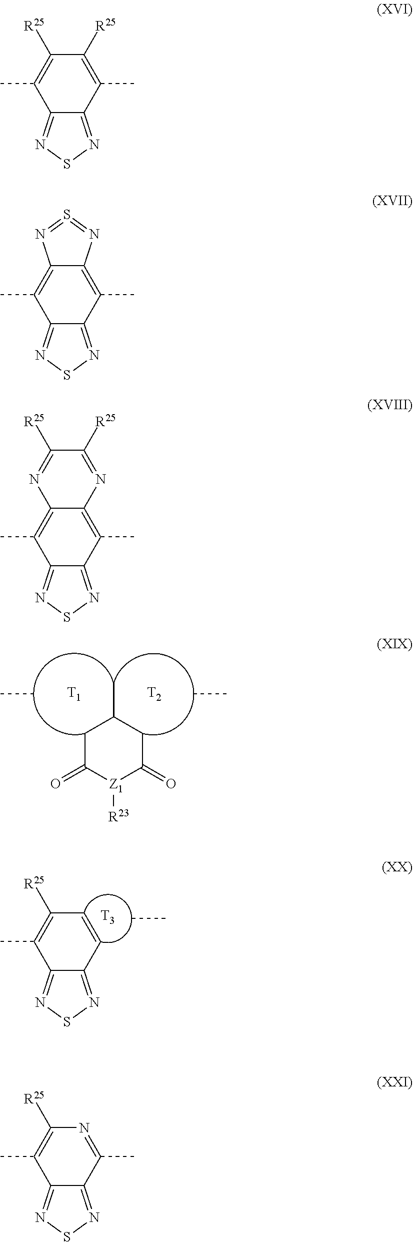 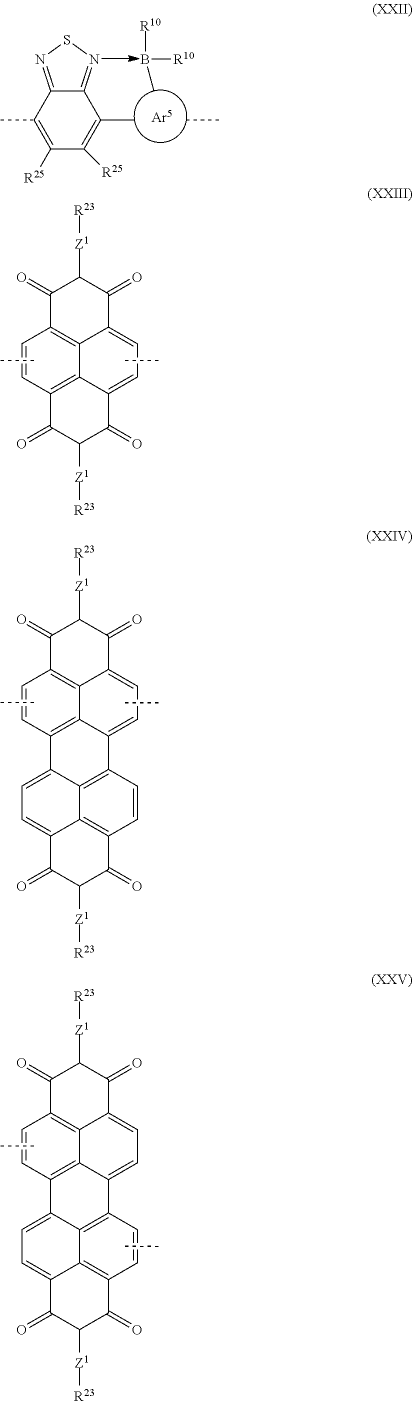
wherein R²³ in each occurrence is H or a substituent; R²⁵ in each occurrence is H or a substituent; Z¹ is N or P; T¹, T² and T³ each independently represent an aryl or a heteroaryl ring which may be fused to one or more further rings; R¹⁰ in each occurrence is a substituent; and Ar⁵ is an arylene or heteroarylene group which is unsubstituted or substituted with one or more substituents.

9. The composition according to claim 1, wherein the organic electron acceptor is a fullerene compound.

10. The composition according to claim 1, wherein the organic electron acceptor is a non-fullerene compound.

11. The composition according to claim 1 wherein the weight of the first donor material is at least the same as the weight of the second donor material

12. A formulation comprising one or more solvents and a composition according to claim 1 dissolved or dispersed in the one or more solvents.

13. An organic photoresponsive device comprising an anode, a cathode and an organic photosensitive layer disposed between the anode and the cathode, wherein the organic photosensitive layer comprises a composition according to claim 1.

14. An organic photoresponsive device according to claim 13 wherein the organic photoresponsive device is an organic photodetector.

15. A method of forming an organic photoresponsive device according to claim 13 comprising formation of the organic photosensitive layer over one of the anode and cathode and formation of the other of the anode and cathode over the organic photosensitive layer.

16. A photosensor comprising a light source and an organic photoresponsive device according to claim 13 configured to detect light emitted from the light source.

17. A photosensor according to claim 16 wherein the light source emits light having a peak wavelength of greater than 900 nm.

18. A method of determining the presence and/or concentration of a target material in a sample, the method comprising illuminating the sample and measuring a response of an organic photoresponsive device as claimed in claim 13.
